(19) United States
(12) Patent Application Publication
(10) Pub. No.: US 2024/0429476 A1
(43) Pub. Date: Dec. 26, 2024

(54) BATTERY PACK AND BATTERY PACK MANAGEMENT SYSTEM

(71) Applicant: Nuvoton Technology Corporation Japan, Kyoto (JP)

(72) Inventors: Naoto AKUTSU, Osaka (JP); Hitoshi KOBAYASHI, Osaka (JP); Keiichi FUJII, Shiga (JP); Akira KAWABE, Osaka (JP)

(21) Appl. No.: 18/823,206

(22) Filed: Sep. 3, 2024

Related U.S. Application Data
(63) Continuation of application No. PCT/JP2023/008352, filed on Mar. 6, 2023.
(60) Provisional application No. 63/317,226, filed on Mar. 7, 2022.

(51) Int. Cl. H01M 10/48; G01R 31/36; G01R 31/371; G01R 31/387; G01R 31/392; H01M 10/42

(52) U.S. Cl. CPC H01M 10/48; G01R 31/3648; G01R 31/371; G01R 31/387; G01R 31/392; H01M 10/4257; H01M 2010/4271; H01M 2010/4278

(57) ABSTRACT

A battery pack includes: a cell stack including secondary cells connected in series or parallel; a cell data calculator that calculates the SOC and the SOH of the secondary cells; and a first NFC unit that uses NFC to communicate with an external device regarding cell information related to the SOC and the SOH calculated by the cell data calculator.

### CROSS REFERENCE TO RELATED APPLICATIONS

This is a continuation application of PCT International Application No. PCT/JP2023/008352 filed on Mar. 6, 2023, designating the United States of America, which is based on and claims priority of U.S. Provisional Patent Application No. 63/317,226 filed on Mar. 7, 2022. The entire disclosures of the above-identified applications, including the specifications, drawings, and claims are incorporated herein by reference in their entirety.

### FIELD

The present disclosure relates to a battery pack and a battery pack management system, and particularly to a battery pack that includes a cell stack including a plurality of secondary cells such as lithium-ion cells, and a system that manages the battery pack.

### BACKGROUND

In recent years, applications that use secondary cells, such as environment-friendly vehicles including electric vehicles as well as storage batteries for stably supplying renewable energy have been increasing rapidly. In many cases, lithium-ion cells (also referred to as lithium-ion batteries (LiB)) are used as secondary cells for their high energy density.

Patent Literature (PTL) 1 proposes a method and device for turning on an e-bike, in which a wireless-communication type battery pack includes a near field communication (NFC) module, and power is supplied directly from the battery pack to an electronic control unit (ECU) of the e-bike by wireless drive.

The technique of PTL 1 includes equipping the battery pack with a wireless communication (NFC or Bluetooth (registered trademark)) module and activating the battery pack by mutual wireless communication authentication between the NFC module of the battery pack and an external device. The mutual wireless communication authentication compares an identification number stored in the NFC module of the battery pack with a unique identification number stored in the external device, and generates a driving signal when the unique identification number matches.

### CITATION LIST

### Patent Literature

PTL 1: U.S. Pat. App. Pub. No. 2022/0295275

### SUMMARY

### Technical Problem

However, with the technique of PTL 1, since the battery pack may be activated by the external device without considering the charge state of the battery pack, there is a possibility that the e-bike cannot be started depending on the battery pack equipped on the e-bike.

For example, if the battery pack equipped on the e-bike has degraded, the internal resistance of the battery pack is increased compared to the initial internal resistance, and the voltage of the battery pack at startup may be insufficient due to the voltage drop at the internal resistance of the battery, leading to cases where the e-bike cannot be started.

The present disclosure was conceived to overcome such problems, and has an object to provide a battery pack with excellent convenience that makes it possible to easily ascertain the charge state of the battery pack using an external device, and a battery pack management system that manages such a battery pack.

### Solution to Problem

In order to achieve the above-described object, a battery pack according to one aspect of the present disclosure includes: a cell stack including secondary cells connected in series or parallel; a cell data calculator that calculates a state of charge (SOC) and a state of health (SOH) of the secondary cells; and a first near field communication (NFC) unit that uses NFC to communicate with an external device regarding cell information related to the SOC and the SOH calculated by the cell data calculator.

In order to achieve the above-described object, a battery pack management system according to one aspect of the present disclosure includes: at least one battery pack each of which is the battery pack described above; and an external device including: a second NFC unit that obtains the cell information from the at least one battery pack via the first NFC unit; and a controller that identifies an SOC and an SOH of the at least one battery pack based on the cell information obtained.

### Advantageous Effects

The present disclosure provides a battery pack with excellent convenience that makes it possible to easily ascertain the charge state of the battery pack using an external device, and a battery pack management system that manages such a battery pack.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A is an external view of a battery pack management system according to an embodiment of the present disclosure.

FIG. 1B is a block diagram illustrating a detailed configuration of the battery pack management system illustrated in FIG. 1A.

FIG. 2 is for explaining an SOC calculation method.

FIG. 3A is for explaining an SOH calculation method.

FIG. 3B is for explaining an example of normalization of a Nyquist plot of impedance of a cell with temperature as a parameter.

FIG. 4 is a flowchart illustrating operations performed in a battery pack to calculate the SOC and SOH of the battery pack.

FIG. 5 is a flowchart illustrating processing procedures in an e-bike rental system, which is one example of a battery pack management system according to Implementation Example 1.

FIG. 6 is a flowchart illustrating processing procedures in a battery pack rental and lease billing system, which is one example of a battery pack management system according to Implementation Example 2.

FIG. 7 is a flowchart illustrating processing procedures in a battery pack reuse system, which is one example of a battery pack management system according to Implementation Example 3.

### DESCRIPTION OF EMBODIMENTS

Hereinafter, embodiments of the present disclosure will be described in detail with reference to the drawings. The embodiments described below each illustrate one specific example of the present disclosure. The numerical values, shapes, materials, elements, the arrangement and connection of the elements, steps, order of the steps, etc., shown in the following embodiments are mere examples, and therefore do not limit the scope of the present disclosure. Accordingly, among the elements in the following implementation examples, those not recited in any of the independent claims are described as optional elements.

The figures are schematic diagrams and are not necessarily precise illustrations. Elements that are essentially the same share the same reference signs in the figures, and duplicate description is omitted or simplified. The phrase “A and B are connected” means that A and B are electrically or communicably connected, and includes not only cases where A and B are directly connected, but also cases where A and B are indirectly connected with other circuit elements or communication devices interposed between A and B.

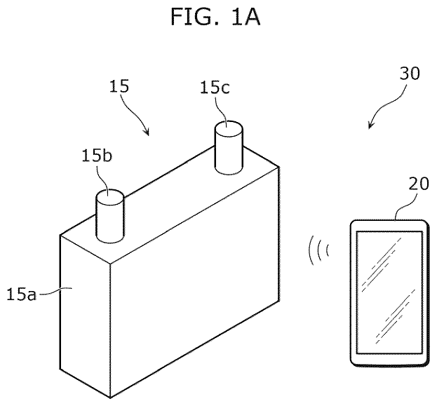

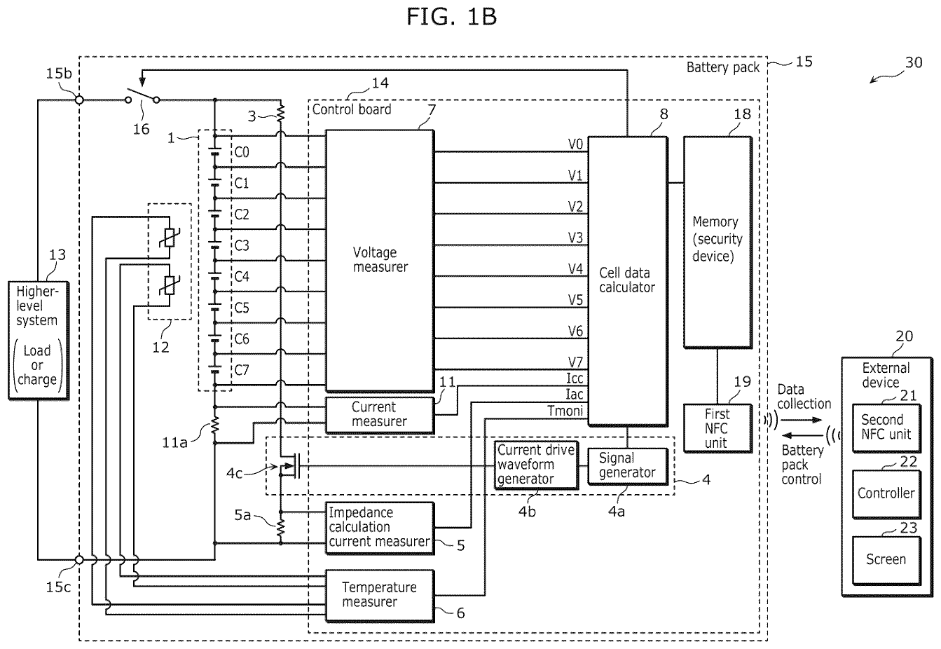

FIG. 1A is an external view of battery pack management system 30 according to an embodiment of the present disclosure. Battery pack management system 30 includes one or more battery packs 15, and external device 20 such as a smartphone that communicates with battery pack 15 by wireless communication.

Battery pack 15 includes housing 15a that houses a cell stack (not illustrated in the drawings) including a plurality of secondary cells (hereinafter also simply referred to as “cells”) such as lithium-ion cells, and has functions of calculating a state of charge (SOC) and a state of health (SOH) of the cell stack and providing cell information related to the calculated SOC and SOH of the cell stack to external device 20 by wireless communication. Positive electrode 15b and negative electrode 15c of the cell stack are provided exposed on housing 15a.

External device 20 communicates with battery pack 15 by wireless communication to obtain the SOC and SOH of battery pack 15 and performs processing such as displaying the SOC and SOH on a built-in screen, thereby assisting in avoiding conventional problems such as starting an e-bike with a degraded battery pack.

FIG. 1B is a block diagram illustrating a detailed configuration of battery pack management system 30 illustrated in FIG. 1A. In addition to battery pack 15 and external device 20 of battery pack management system 30, FIG. 1B also illustrates higher-level system 13 such as an e-bike that receives a supply of power from battery pack 15.

Battery pack 15 includes cell stack 1, thermistor 12, and control board 14 as main elements housed in housing 15a.

Cell stack 1 includes cells C0 through C7 (hereinafter, any one of cells C0 through C7 is also referred to as “cell C” or “cell Cn”). Stated differently, cell C is a single cell (that is, a battery cell). Cell C is specifically a lithium-ion cell, but may be any other cell such as a nickel metal hydride cell, etc. Cell stack 1 functions as a power supply and supplies power to higher-level system 13 (specifically, a load such as a motor, inverter, accelerator, etc., of an e-bike or the like, or a charger, etc.).

Control board 14 includes voltage measurer 7, current measurer 11, temperature measurer 6, alternating current (AC) current excitator 4, impedance calculation current measurer 5, cell data calculator 8, memory 18, and first NFC unit 19. Control board 14 is included in, for example, a battery management system (BMS). Control board 14 includes, for example, one or more integrated circuits and a circuit board on which the one or more integrated circuits are mounted. Voltage measurer 7 measures voltage Vn of cells C0 through C7.

Current measurer 11 measures current Icc that flows through reference resistor 11a connected in series with cells C0 through C7.

Temperature measurer 6 measures temperature Tmoni detected by thermistor 12 disposed in proximity to cell stack 1. Thermistor 12 is one example of a temperature sensor and may be a temperature sensor that uses a different element such as a thermocouple. Temperature Tmoni measured by temperature measurer 6 may be used to normalize the impedances of cells C0 through C7 calculated by cell data calculator 8 to an arbitrary temperature (for example, 25° C.).

AC current excitator 4 is a circuit that sweeps an AC signal for excitating current flowing through cell stack 1, and includes signal generator 4a that generates a signal for sweeping, current drive waveform generator 4b that generates an AC current drive waveform based on the signal for sweeping generated by signal generator 4a, and transistor 4c that changes a conduction state according to the current drive waveform generated by current drive waveform generator 4b.

Impedance calculation current measurer 5 measures current Iac flowing through reference resistor 5a.

Cell data calculator 8 starts up in response to an instruction from external device 20 via first NFC unit 19, calculates the SOC and SOH of cells C0 through C7 of cell stack 1, and stores the calculated SOC and SOH in memory 18.

Here, the SOC, etc., of cells C0 through C7 (or, a plurality of cells C0 through C7, or, cell stack 1) means the SOC, etc., of each of cells C0 through C7. The SOC, etc., of battery pack 15 means a single SOC, etc., representing the SOC, etc., of cells C0 through C7.

To calculate the SOC and SOH of cells C0 through C7, cell data calculator 8 first measures the impedances of cells C0 through C7 using the AC impedance method. More specifically, cell data calculator 8 controls AC current excitator 4 so as to apply a control signal for sweeping an AC signal for excitating current flowing through cell stack 1 to a control terminal of transistor 4c connected in series with load resistor 3 and reference resistor 5a, measures current Iac flowing through reference resistor 5a using impedance calculation current measurer 5, and measures voltage Vn of cell Cn using voltage measurer 7. Cell data calculator 8 then converts the measured current Iac to a complex current and converts the measured voltage Vn to a complex voltage, performs an averaging process of averaging the complex currents and an averaging process of averaging the complex voltages, and calculates the impedance of cell Cn by dividing the complex voltage resulting from the complex voltage averaging process by the complex current resulting from the complex current averaging process. Here, n is any one of 0 to 7. Each of the impedances is a complex number and has a real component and an imaginary component.

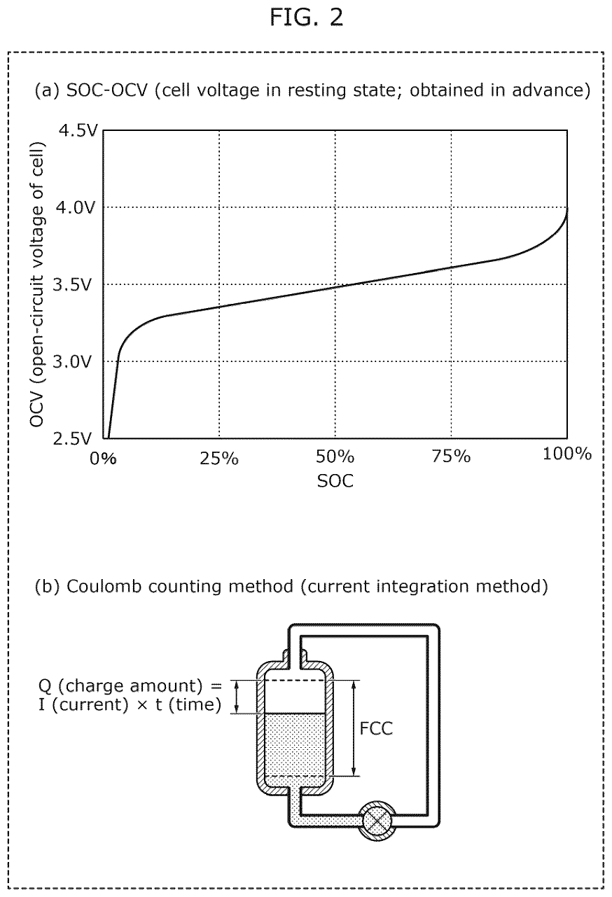

Cell data calculator 8 then calculates the SOC of cells C0 through C7. FIG. 2 is for explaining the SOC calculation method. More specifically, (a) in FIG. 2 illustrates an SOC-open circuit voltage (OCV) correlation table obtained and stored in memory 18 in advance, and (b) in FIG. 2 illustrates an outline of the coulomb counting method (current integration method) that may be used when calculating the SOC. Cell data calculator 8 measures the voltage of cells C0 through C7 when battery pack 15 stops supplying power (i.e., when battery pack 15 stops), and calculates the SOC of cells C0 through C7 by referencing the SOC-OCV correlation table using those voltages as OCVs. However, within 30 minutes after battery pack 15 stops, the secondary cells are not yet stable and an accurate OCV cannot be measured, so cell data calculator 8 adopts, as the SOC, the final value obtained by the coulomb counting method ((b) in FIG. 2) that measures the SOC while driving by subtracting the change amount obtained by current integration from the starting SOC.

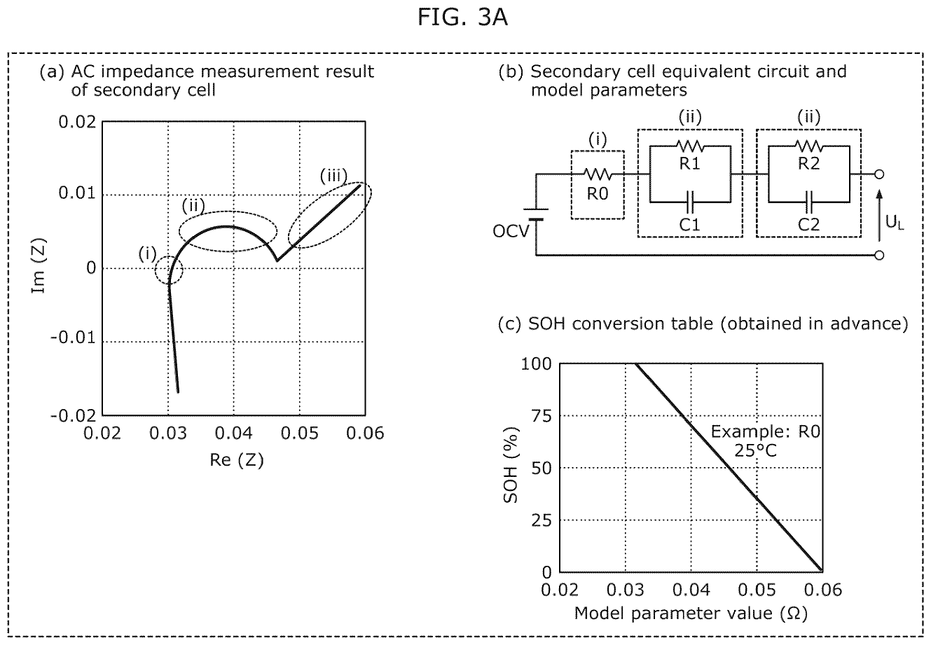

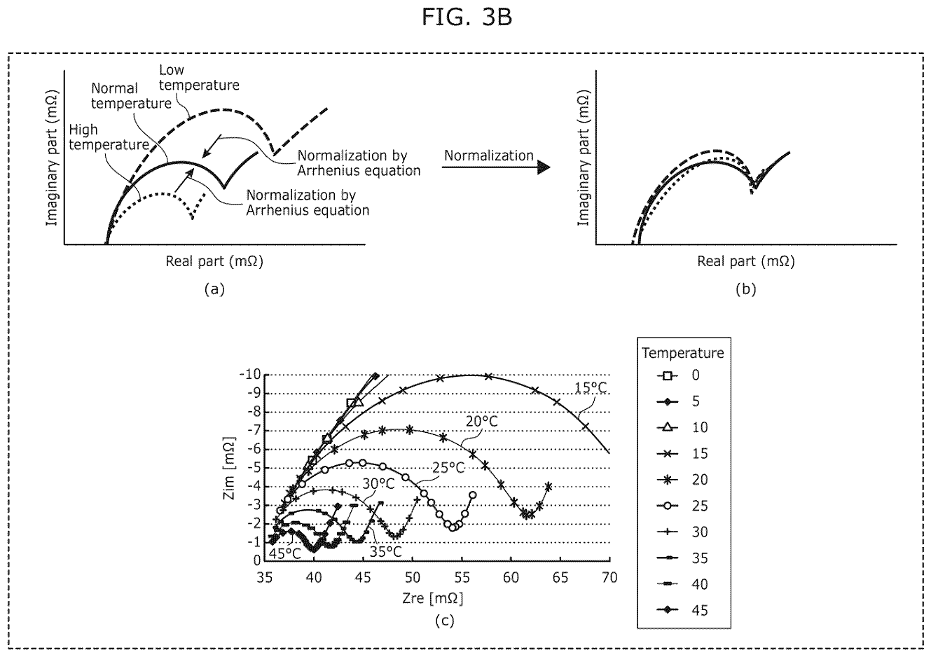

Furthermore, cell data calculator 8 calculates the SOH of cells C0 through C7 using the calculated impedances of cells C0 through C7. FIG. 3A is for explaining the SOH calculation method. More specifically, (a) in FIG. 3A illustrates an example of impedance measurement results of cell C measured by the AC impedance method, (b) in FIG. 3A illustrates an equivalent circuit and model parameters of cell C, and (c) in FIG. 3A illustrates an example of model parameter-SOH correlation data obtained and stored in memory 18 in advance. Cell data calculator 8 first measures the impedance of cell C using the above-described AC impedance method to obtain a Nyquist plot of the impedance as illustrated in (a) in FIG. 3A. Next, cell data calculator 8 focuses on a specific frequency band in the obtained Nyquist plot and fits it to the equivalent circuit illustrated in (b) in FIG. 3A to obtain model parameters of the equivalent circuit corresponding to each of the frequency bands (i), (ii), and (iii) in (a) in FIG. 3A. Next, using the obtained model parameters of the equivalent circuit corresponding to each of the frequency bands (i), (ii), and (iii), the SOH of cell C is calculated by referencing the model parameter-SOH correlation data illustrated in (c) in FIG. 3A. FIG. 3A illustrates a calculation example in which model parameter R0 corresponding to the region of frequency band (i) in the Nyquist plot of the impedance is used, and the correlation between model parameter R0 and SOH is measured in advance and tabulated as a correlation table.

Here, since the Nyquist plot and the model parameters in the equivalent circuit vary with changes in temperature, the normalization illustrated in FIG. 3B may be performed to convert them to a standard temperature such as 25° C. (for example, conversion by table lookup), thereby removing the influence of temperature variations. FIG. 3B is for explaining an example of normalization of a Nyquist plot of impedance of a cell with temperature as a parameter. More specifically, (a) in FIG. 3B illustrates an example of a plurality of Nyquist plots at different temperatures before normalization, (b) in FIG. 3B illustrates an example of a plurality of Nyquist plots after normalization, and (c) in FIG. 3B illustrates an example of temperature dependency of Nyquist plots when the temperature is varied without performing normalization. Since the Nyquist plot of the impedance of a cell exhibits a change that follows the Arrhenius equation with respect to temperature, the Arrhenius coefficient can be determined by obtaining the temperature variation characteristics of the Nyquist plot of the impedance for the same type of cell in advance. Based on the determined Arrhenius coefficient, normalization can be performed to convert the Nyquist plot corresponding to an arbitrary temperature of the same type of measured cell to a Nyquist plot at the standard temperature.

Cell data calculator 8 also controls cutoff device 16 to electrically isolate the connection between higher-level system 13 and battery pack 15 during an anomaly or sleep state of battery pack 15.

Memory 18 is a secure device and holds, as cell information, various values prepared in advance (SOC-OCV correlation table, model parameter-SOH correlation data, nominal capacity (full charge capacity (FCC)) of battery pack 15, etc.), as well as measured values and calculated values such as the voltage, current, and temperature of cells C0 through C7 of cell stack 1 obtained by voltage measurer 7, current measurer 11 including reference resistor 11a, and temperature measurer 6, and the impedance, SOC, and SOH, etc., of cells C0 through C7 calculated by cell data calculator 8.

Cell data calculator 8 may calculate or select a representative SOC and a representative SOH of battery pack 15 based on the SOC and SOH of cells C0 through C7, and save them in memory as the SOC and SOH of battery pack 15. The SOC and SOH of battery pack 15 are, for example, the minimum SOC and SOH among the SOC and SOH of cells C0 through C7, or the average values of the SOC and SOH of cells C0 through C7.

First NFC unit 19 enables measurement of the voltage, current, and temperature of cell stack 1 (i.e., cells C0 through C7) by controlling control board 14 from external device 20 through NFC wireless communication (i.e., short-range wireless communication according to the NFC standard or Bluetooth (registered trademark) standard, etc.) with external device 20 equipped with second NFC unit 21. Furthermore, first NFC unit 19 enables external device 20 to access memory 18 via first NFC unit 19 and read out the cell information stored in memory 18.

External device 20 includes second NFC unit 21, controller 22, and screen 23. Second NFC unit 21 is an interface for NFC wireless communication (i.e., short-range wireless communication according to the NFC standard or Bluetooth (registered trademark) standard, etc.) for obtaining cell information from battery pack 15 via first NFC unit 19. Controller 22 includes a processor, etc., that identifies the SOC and SOH of battery pack 15 based on the obtained cell information. Screen 23 is a screen such as an LCD that displays images and various information.

Here, external device 20 identifying the SOC and SOH of battery pack 15 based on the cell information obtained from battery pack 15 may mean that external device 20 directly obtains the representative SOC and SOH of battery pack 15, i.e., the SOC and SOH of battery pack 15, from battery pack 15, or it may mean that external device 20 first obtains the SOC and SOH of cells C0 through C7 from battery pack 15, and then external device 20 calculates the representative SOC and SOH of battery pack 15, i.e., the SOC and SOH of battery pack 15, from the obtained SOC and SOH of cells C0 through C7.

HereThe phrase “external device 20 performs some operation” means in a strict sense that controller 22 of external device 20 performs some operation as the main actor, but “controller 22 of external device 20 performs some operation” can also be simply stated as “external device 20 performs some operation”.

HereNext, operations performed by battery pack management system 30 according to the present embodiment configured as described above will be described.

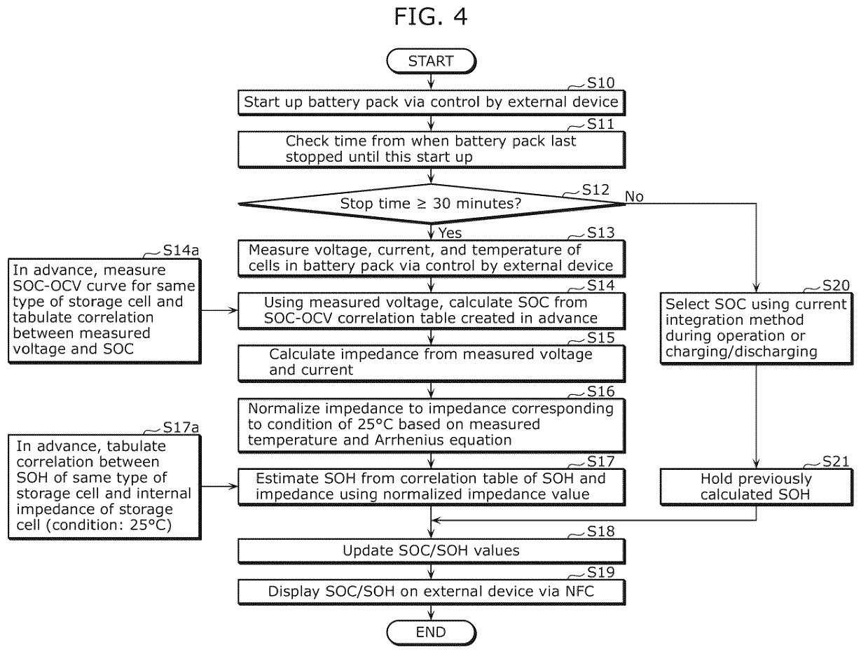

FIG. 4 is a flowchart illustrating operations performed in battery pack 15 to calculate the SOC and SOH of battery pack 15. Here, the procedure by which the SOC and SOH of battery pack 15 are diagnosed (i.e., identified) by external device 20 is shown.

In battery pack 15, when cell data calculator 8 receives an instruction to start up from external device 20 via first NFC unit 19 (S10), cell data calculator 8 obtains the stop time of battery pack 15 (i.e., the time from the last stop until receiving the instruction to start up this time) by referencing a built-in timer (S11).

Cell data calculator 8 then determines whether the obtained stop time of battery pack 15 is greater than or equal to 30 minutes (S12), and if it is greater than or equal to 30 minutes (Yes in S12), obtains a measured voltage, a measured current, and a measured temperature by measuring the voltage, current, and temperature of cell stack 1 (S13). Next, using the measured voltage, cell data calculator 8 calculates the SOC of cell stack 1 by referencing SOC-OCV correlation table S14a, which is created and stored in memory 18 in advance (S14).

Next, cell data calculator 8 calculates the impedance of cell stack 1 from the measured voltage and measured current (S15). Cell data calculator 8 then normalizes the calculated impedance to an impedance at an arbitrary temperature (for example, 25° C.) based on the measured temperature and the Arrhenius equation (S16). Furthermore, using the normalized impedance, cell data calculator 8 calculates the SOH of cell stack 1 by referencing correlation table 17a of SOH and impedance, which is created and stored in memory 18 in advance (S17).

However, when the obtained stop time of battery pack 15 is not greater than or equal to 30 minutes in the determination of step S12 above (No in S12), cell data calculator 8 calculates the SOC of cell stack 1 using the coulomb counting method described above (S20), and maintains the previously calculated SOH for cell stack 1 (S21).

HereCell data calculator 8 stores the newly calculated SOC and SOH in memory 18 as the latest values (S18), and also notifies external device 20 of the newly calculated SOC and SOH.

HereExternal device 20, having received a notification from cell data calculator 8, calculates the SOC and SOH of battery pack 15, which are the representative values of the notified SOC and SOH of cell stack 1, and displays the calculated SOC and SOH of battery pack 15 on screen 23 or uses them in various applications of battery pack management system 30, which will be described later (S19).

When cell data calculator 8 calculates the SOC and SOH of battery pack 15 as representative values and stores them in memory 18 instead of external device 20 doing so, external device 20, having received notification of the SOC and SOH of battery pack 15 from cell data calculator 8, displays the notified SOC and SOH of battery pack 15 on screen 23 or uses them in various applications of battery pack management system 30, which will be described later.

Hereinafter, Implementation Examples 1 to 3 will be described as various applications of battery pack management system 30.

### Implementation Example 1

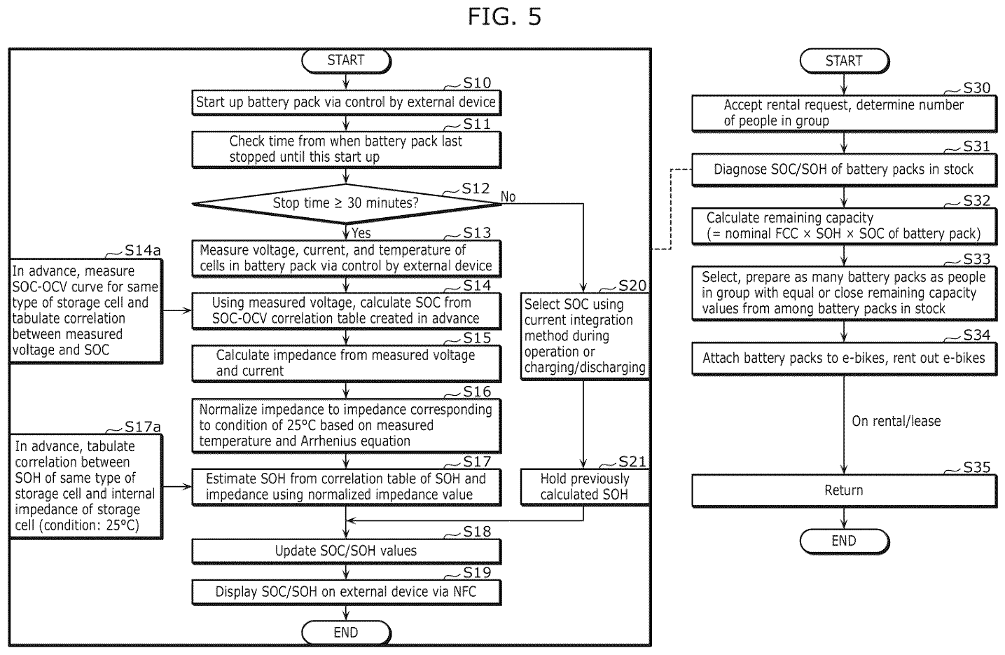

FIG. 5 is a flowchart illustrating processing procedures in an e-bike rental system, which is one example of battery pack management system 30 according to Implementation Example 1. Here, a flowchart is shown in which processing procedures specific to the e-bike rental system (S30 to S35) are added to the flowchart (S10 to S21) illustrated in FIG. 4. The e-bike rental system is a business that lends out e-bikes, which are one example of the electric device, attached with battery pack 15 according to an embodiment of the present disclosure.

Suppose a plurality (i.e., a group) of people come to an e-bike rental store and request to rent out one e-bike for each person in the group. In this case, the store first accepts the request to rent out e-bikes and determines the number of people in the group, i.e., the number of battery packs 15 required (S30).

The store diagnoses the SOC and SOH of each of battery packs 15 that it has available (hereinafter also referred to as “battery packs 15 in stock”) (S31). More specifically, for each of battery packs 15 in stock, the SOC and SOH are obtained by performing the processing of steps S10 to S21 in this figure using external device 20, or by referencing values that have already been calculated.

Furthermore, using the nominal capacity FCC of the battery packs to be rented out obtained from battery pack 15 and the like, external device 20 calculates the remaining battery capacity (hereinafter also referred to as the usable remaining capacity) for each of battery packs 15 in stock by calculating FCC x SOH x SOC (S32).

External device 20 references the calculated remaining battery capacity of each of battery packs 15 in stock, selects battery packs 15 with equal or close remaining battery capacity values for the number of people renting, and displays them on the built-in screen (S33). The store carries out the rental of e-bikes for the number of people renting by attaching the selected battery packs 15 to e-bikes (S34).

Thereafter, when the rental/lease of the e-bikes ends, the store receives the returned rented out e-bikes, and the series of e-bike rental services ends (S35).

Thus, by equipping e-bikes with battery packs 15 having equal or close remaining battery capacity values and renting them out to a group, it becomes possible to proactively inhibit troubles such as only one e-bike in the group running out of power and becoming unable to travel during the rental period.

Note that if the duration between the Nyquist plot at the time of diagnosing battery pack 15 immediately before rental and the Nyquist plot at the time of diagnosing battery pack 15 either one time prior or over a certain time series is short, the degradation level will not be large, and the Nyquist plots will also yield almost the same results. If the shape of a Nyquist plot is clearly different, or if a discontinuous Nyquist plot is seen in the time series data, by determining not to rent out that battery pack 15 as a defective product, troubles such as sudden stops after rental can be proactively inhibited.

In the present implementation example, an e-bike, which is one example of an electric device, has been described as an example of what is to be rented, but examples of electric devices are not limited to this, and as long as it is an electric device in which a battery pack is equipped, such as an e-scooter, drone, commuter vehicle, etc., if it is a device that can be rented, the processing procedures of this e-bike rental system can be applied.

### Implementation Example 2

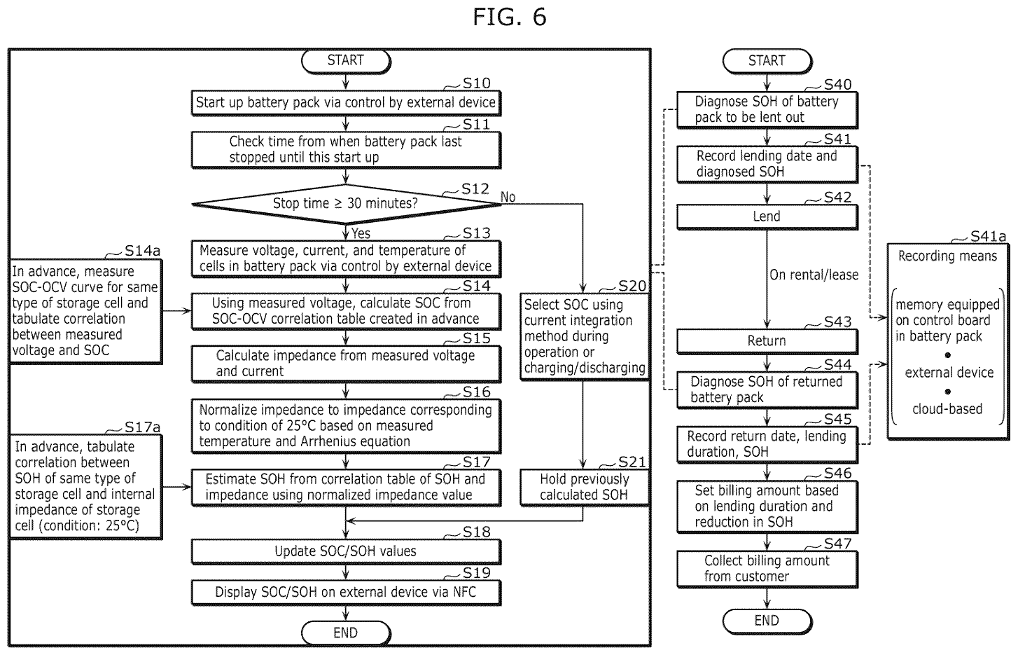

FIG. 6 is a flowchart illustrating processing procedures in a battery pack rental and lease billing system, which is one example of battery pack management system 30 according to Implementation Example 2. Here, a flowchart is shown in which processing procedures specific to the battery pack rental and lease billing system (S40 to S47) are added to the flowchart (S10 to S21) illustrated in FIG. 4. The battery pack rental and lease billing system is a business that rents/leases battery packs 15 themselves. Here, rent/lease means the business either rents or leases battery pack 15, and is also simply referred to as “lending”.

Prior to renting/leasing battery pack 15, the renter/leaser (hereinafter referred to as the “lender”) diagnoses the SOH of battery pack 15 to be lent out (S40) using external device 20 in accordance with steps S10 to S21 in this figure, records the lending date and the SOH of battery pack 15 in memory 18 of battery pack 15, memory included in external device 20, or recording means S41a such as a cloud-based recording means connected via a communication network (S41), and then lends out battery pack 15 (S42).

When the rental/lease duration ends and battery pack 15 is returned to the lender (S43), the lender again diagnoses the SOH of battery pack 15 using external device 20 at the time of the return (S44), and records the return date, lending duration, and the SOH of battery pack 15 in recording means S41a (S45).

External device 20 accesses recording means S41a to calculate the billing amount according to the lending duration and the amount of reduction in the SOH (i.e., the difference between the SOH of battery pack 15 diagnosed before and after the rental/lease) (S46). The lender bills the user for the billing amount calculated by external device 20 and collects the billing amount (S47).

Thus, in the present implementation example, the SOH of battery pack 15 can be diagnosed on the spot both at the time of lending and at the time of returning, thereby ensuring the billing calculation and billing according to the amount of reduction in SOH during the rental/lease duration, and enabling operation of a battery pack rental and lease billing system in which the amount of reduction in the battery residual value of battery pack 15 due to the user's usage is appropriately reflected.

Note that if the duration between the Nyquist plot at the time of diagnosing battery pack 15 immediately before rental and the Nyquist plot at the time of diagnosing battery pack 15 either one time prior or over a certain time series is short, the degradation level will not be large, and the Nyquist plots will also yield almost the same results. If the shape of a Nyquist plot is clearly different, or if a discontinuous Nyquist plot is seen in the time series data, by determining not to rent out that battery pack 15 as a defective product, troubles such as sudden stops after rental can be proactively inhibited.

### Implementation Example 3

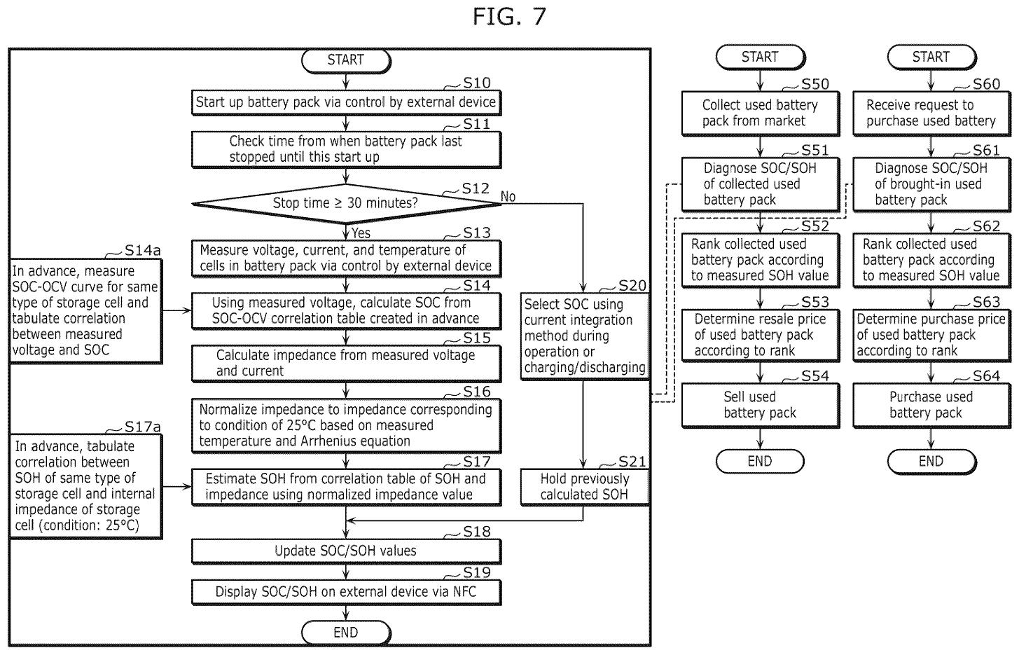

FIG. 7 is a flowchart illustrating processing procedures in a battery pack reuse system, which is one example of battery pack management system 30 according to Implementation Example 3. Here, a flowchart is shown in which processing procedures specific to the battery pack reuse system (S50 to S54, S60 to S64) are added to the flowchart (S10 to S21) illustrated in FIG. 4. The battery pack reuse system is a business that sells battery packs 15 collected from the market as used battery packs 15 (also referred to as the sale of used battery packs) or purchases used battery packs 15 from those who wish to sell (also referred to as the purchase of used battery packs).

In the sale of used battery packs, the operator of the battery pack reuse system first diagnoses the SOC and SOH (S51) of a used battery pack 15 collected from the market (S50) using external device 20 in accordance with steps S10 to S21 in this figure, and ranks the used battery pack 15 based on the obtained SOH (S52). Regarding the ranking, more specifically, external device 20 identifies the rank to which the SOH of the used battery pack 15 belongs by referencing a table that associates each of a plurality of SOH ranges, which are stored in advance, with a rank.

External device 20 determines a resale price of the used battery pack 15 according to the identified rank (S53). More specifically, regarding the determination of the resale price, external device 20 determines the resale price corresponding to the rank of the used battery pack 15 by referencing a table that associates each of a plurality of ranks, which are stored in advance, with a resale price.

The operator resells used battery pack 15 at the determined resale price (S54).

In the purchase of used battery packs, the operator receives a user's request of the operator to purchase a used battery pack 15 (S60), diagnoses the SOC and SOH of the brought-in used battery pack 15 using external device 20 (S61), and ranks the used battery pack 15 based on the obtained SOH (S62). Regarding the ranking, more specifically, as in the case of the sale of used battery packs, external device 20 identifies the rank to which the SOH of used battery pack 15 belongs by referencing a table that is stored in advance.

External device 20 determines a purchase price of used battery pack 15 according to the identified rank (S63). More specifically, regarding the determination of the purchase price, external device 20 determines the purchase price corresponding to the rank of used battery pack 15 by referencing a table that associates each of a plurality of ranks, which are stored in advance, with a purchase price.

The operator purchases used battery pack 15 at the determined purchase price (S64).

Thus, in the present implementation example, since the SOH of a used battery pack 15 can be diagnosed on the spot at the time of purchasing battery pack 15 to determine an accurate battery residual value, battery pack 15 can be purchased at an appropriate price according to the remaining battery capacity. Even when a large quantity of used battery packs 15 are collected, the SOH of each battery pack 15 can be diagnosed in a short time, and the price of battery pack 15 can be set according to the obtained SOH, so the reuse of used battery packs 15 can be accelerated.

Note that in the above examples, in the sale and purchase of used battery packs, the resale price and purchase price are determined based on the SOH after ranking, but ranking is not necessarily required. For example, the resale price and purchase price may be determined according to the following formula based on the SOH.

Resale price or purchase price=price of new battery pack×(SOH−disposal SOH level)/disposal SOH level−fixed reduction value−fee

Here, the price of a new battery pack is a predetermined price of a new battery pack (for example, 10,000 yen), the disposal SOH level is a predetermined value as the SOH at which to dispose of the battery pack (for example, 50%), the fixed reduction value is a predetermined flat-rate reduction value (for example, 1,000 yen), and the fee is a fee for selling or purchasing a used battery pack (for example, 2,000 yen).

As described above, battery pack 15 according to the present embodiment includes: cell stack 1 including secondary cells C0 through C7 connected in series or parallel; cell data calculator 8 that calculates the SOC and the SOH of secondary cells C0 through C7; and first NFC unit 19 that uses NFC to communicate with external device 20 regarding cell information related to the SOC and the SOH calculated by cell data calculator 8.

With this, battery pack 15 includes not only first NFC unit 19 that communicates with external device 20 via NFC, but also cell data calculator 8 that calculates the SOC and SOH of secondary cells C0 through C7. Therefore, external device 20 can easily ascertain the charge state of battery pack 15 by wireless communicating with battery pack 15 via NFC.

Here, cell data calculator 8 calculates the SOC and SOH in response to receiving an instruction from external device 20 via first NFC unit 19. This allows external device 20 to diagnose battery pack 15 at any timing and obtain the SOC and SOH of battery pack 15.

Cell data calculator 8 calculates the SOC and SOH using an AC impedance method. This enables the complex impedance of battery pack 15 to be accurately measured by using a Nyquist plot, and an accurate SOH to be calculated based on the accurate complex impedance.

Battery pack 15 further includes memory 18 that stores the SOC and the SOH calculated by cell data calculator 8. External device 20 accesses memory 18 via first NFC unit 19. This allows the cell information of battery pack 15 to be read out to external device 20 via memory 18.

Battery pack management system 30 according to the present embodiment includes: at least one battery pack 15; and external device 20 including: second NFC unit 21 that obtains the cell information from the at least one battery pack 15 via first NFC unit 19; and controller 22 that identifies an SOC and an SOH of the at least one battery pack 15 based on the cell information obtained. This makes it possible to realize battery pack management system 30 that manages battery pack 15 with excellent convenience.

For example, in an application such as an e-bike rental system, the at least one battery pack 15 includes a plurality of battery packs 15 to be used in a plurality of electric devices, and controller 22 included in external device 20: obtains the cell information from the plurality of battery packs 15 via second NFC unit 21; for each of the plurality of battery packs 15, identifies the SOC and the SOH of battery pack 15 from the cell information obtained, and calculates a usable remaining capacity of battery pack 15 using the SOC and the SOH identified; and based on the usable remaining capacities of the plurality of battery packs 15 calculated, selecting, from among the plurality of battery packs 15, battery packs 15 having close usable remaining capacities, the battery packs 15 selected being fewer in number than the plurality of battery packs 15.

With this, by equipping e-bikes with battery packs 15 having equal or close remaining battery capacity values and renting them out to a group, it becomes possible to proactively inhibit troubles such as only one e-bike in the group running out of power and becoming unable to travel during the rental period.

For example, in an application such as a battery pack rental and lease billing system, controller 22 included in external device 20: at a time of lending out the at least one battery pack 15, identifies the SOH of the at least one battery pack 15 corresponding to a time of lending as a first SOH by obtaining the cell information from the at least one battery pack 15 via second NFC unit 21; at a time of the at least one battery pack 15 lent out being returned, identifies the SOH of the at least one battery pack 15 corresponding to a time of return as a second SOH by obtaining the cell information from the at least one battery pack 15 via second NFC unit 21; and calculates a fee for lending out the at least one battery pack 15 based on a difference between the first SOH and the second SOH, and outputs the fee calculated.

With this, the SOH of battery pack 15 can be diagnosed on the spot both at the time of lending and at the time of returning, resulting in billing calculation and billing according to the amount of reduction in SOH during the rental/lease duration, and enabling operation of a battery pack rental and lease billing system in which the amount of reduction in the battery residual value of battery pack 15 due to the user's usage is appropriately reflected.

For example, in an application such as a battery pack reuse system, the at least one battery pack 15 is a used battery pack 15 to be purchased or a battery pack 15 to be resold, and controller 22 included in external device 20: identifies the SOH of the at least one battery pack 15 by obtaining the cell information from the at least one battery pack 15 via second NFC unit 21; and determines and outputs a resale price or purchase price of the at least one battery pack 15 based on the SOH identified.

This allows the SOH of used battery pack 15 to be diagnosed on the spot at the time of purchasing battery pack 15 to determine an accurate battery residual value, so battery pack 15 can be purchased at an appropriate price according to the remaining battery capacity. Even when a large quantity of used battery packs 15 are collected, the SOH of each battery pack 15 can be diagnosed in a short time, and the price of battery pack 15 can be set according to the obtained SOH, so the reuse of used battery packs 15 can be accelerated.

When determining the resale price or the purchase price, controller 22 included in external device 20 ranks the at least one battery pack 15 based on the SOH identified, and determines the resale price or the purchase price of the at least one battery pack 15 according to the rank. This simplifies the procedures for buying and selling and improves convenience for operators and users of the battery pack reuse system since the resale price or purchase price is discretized and the number of possible price points is reduced.

Hereinbefore, battery pack 15 and battery pack management system 30 according to the present disclosure have been described based on embodiments and implementation examples, but the present disclosure is not limited to these embodiments and implementation examples. Various modifications to the embodiments and implementation examples that may be conceived by those skilled in the art, as well as other embodiments resulting from combinations of some elements of the embodiments and implementation examples, are intended to be included within the scope of the present disclosure as long as these do not depart from the essence of the present disclosure.

For example, in the above embodiments, to diagnose battery pack 15, battery pack 15 starts up in response to an instruction from external device 20 and calculates the SOC and SOH, but instead or in addition to this, battery pack 15 may start up on its own at certain intervals using a built-in timer or the like to calculate the SOC and SOH and store them in memory 18.

In the above embodiment, battery pack 15 overwrites data in memory 18 with the calculated values such as the SOC and SOH as the latest values, but instead of overwriting, the calculated values may be accumulatively recorded within the storage capacity of memory 18.

In the above embodiments, battery pack 15 stores the SOC and SOH of cells C0 through C7 in memory 18, but the embodiments are not limited to this. Instead of storing the SOC and SOH of cells C0 through C7 in memory 18, only representative SOC and SOH values of battery pack 15 calculated from the SOC and SOH of cells C0 through C7 may be stored in memory 18.

Cell data calculator 8 and controller 22 of external device 20 may be implemented by a processor executing a program or by dedicated electronic circuitry. 5

### INDUSTRIAL APPLICABILITY

The present disclosure is applicable as a battery pack that includes a function of monitoring the state of secondary cells such as lithium-ion secondary cells, and a battery pack management system that manages such a battery pack.

1. A battery pack comprising:
a cell stack including secondary cells connected in series or parallel;
a cell data calculator that calculates a state of charge (SOC) and a state of health (SOH) of the secondary cells; and
a first near field communication (NFC) unit that uses NFC to communicate with an external device regarding cell information related to the SOC and the SOH calculated by the cell data calculator.

2. The battery pack according to claim 1, wherein
the cell data calculator calculates the SOC and the SOH in response to receiving an instruction from the external device via the first NFC unit.

3. The battery pack according to claim 1, wherein
the cell data calculator calculates the SOC and the SOH using an alternating current (AC) impedance method.

4. The battery pack according to claim 1, further comprising:
memory that stores the SOC and the SOH calculated by the cell data calculator, wherein
the external device accesses the memory via the first NFC unit.

5. A battery pack management system comprising:
at least one battery pack each of which is the battery pack according to claim 1; and
an external device including: a second NFC unit that obtains the cell information from the at least one battery pack via the first NFC unit; and a controller that identifies an SOC and an SOH of the at least one battery pack based on the cell information obtained.

6. The battery pack management system according to claim 5, wherein
the at least one battery pack comprises a plurality of battery packs to be used in a plurality of electric devices, and
the controller included in the external device:
obtains the cell information from the plurality of battery packs via the second NFC unit;
for each of the plurality of battery packs, identifies the SOC and the SOH of the battery pack from the cell information obtained, and calculates a usable remaining capacity of the battery pack using the SOC and the SOH identified; and
based on the usable remaining capacities of the plurality of battery packs calculated, selecting, from among the plurality of battery packs, battery packs having close usable remaining capacities, the battery packs selected being fewer in number than the plurality of battery packs.

7. The battery pack management system according to claim 5, wherein
the controller included in the external device:
at a time of lending out the at least one battery pack, identifies the SOH of the at least one battery pack corresponding to a time of lending as a first SOH by obtaining the cell information from the at least one battery pack via the second NFC unit;
at a time of the at least one battery pack lent out being returned, identifies the SOH of the at least one battery pack corresponding to a time of return as a second SOH by obtaining the cell information from the at least one battery pack via the second NFC unit; and
calculates a fee for lending out the at least one battery pack based on a difference between the first SOH and the second SOH, and outputs the fee calculated.

8. The battery pack management system according to claim 5, wherein
the at least one battery pack is a used battery pack to be purchased or a battery pack to be resold, and
the controller included in the external device:
identifies the SOH of the at least one battery pack by obtaining the cell information from the at least one battery pack via the second NFC unit; and
determines and outputs a resale price or purchase price of the at least one battery pack based on the SOH identified.

9. The battery pack management system according to claim 8, wherein
when determining the resale price or the purchase price, the controller included in the external device ranks the at least one battery pack based on the SOH identified, and determines the resale price or the purchase price of the at least one battery pack according to the rank.
